(19) United States
(12) Patent Application Publication
(10) Pub. No.: US 2016/0124044 A1
(43) Pub. Date: May 5, 2016

(54) FAILURE DIAGNOSIS SYSTEM, FAILURE DIAGNOSIS METHOD, AND FAILURE DIAGNOSIS PROGRAM

(71) Applicant: RENESAS ELECTRONICS CORPORATION, Tokyo (JP)

(72) Inventor: Junpei NONAKA, Ibaraki (JP)

(21) Appl. No.: 14/927,247

(22) Filed: Oct. 29, 2015

(30) Foreign Application Priority Data
Oct. 30, 2014 (JP) 2014-221335

(51) Int. Cl. G01R 31/317; G01R 31/3177

(52) U.S. Cl. CPC G01R 31/31726; G01R 31/3177

(57) ABSTRACT

This present invention is to obtain the appropriate number of fails by optimizing test conditions for a delay failure diagnosis. In a failure diagnosis system of an embodiment, a control unit controls a test device to test an integrated circuit a plurality of times while changing the test conditions to collect a fail log. A creation unit creates a test result map on the basis of the fail log. An extraction unit performs route tracking from a fail flip-flop in the fail log to obtain a primary failure candidate. An analysis unit computes by a simulation the delay and timing margin of the fail flip-flop in the fail log. A computing unit computes a matching degree between the timing margin of the simulation result and the test result map for each primary failure candidate. An output unit outputs a candidate having a high matching degree as a failure candidate.

### CROSS-REFERENCE TO RELATED APPLICATIONS

The disclosure of Japanese Patent Application No. 2014-221335 filed on Oct. 30, 2014 including the specification, drawings, and abstract is incorporated herein by reference in its entirety.

### BACKGROUND

The present invention relates to a failure diagnosis technique, and particularly to a failure diagnosis system, a failure diagnosis method, and a failure diagnosis program for a delay failure in a logic part of a semiconductor integrated circuit.

A failure diagnosis for a semiconductor integrated circuit is a technique to estimate a failure spot using software on the basis of a test result. For example, a primary failure candidate is obtained by route tracking, and a failure propagation route from the candidate and a timing margin are computed by a simulation in the failure diagnosis using scan flip-flops. Next, a timing margin s1 of a fail flip-flop and a timing margin s2 of a pass flip-flop are compared with each other. When s1>s2, it is determined that the candidate is inconsistent with the test result. Then, a spot with a small degree of inconsistency is output as a failure candidate. Such a failure diagnosis for a semiconductor integrated circuit using scan flip-flops is described in, for example, Japanese Patent Nos. 5292164, 5381591, and 4020731.

Japanese Patent No. 5292164 relates to a failure diagnosis for a semiconductor integrated circuit, and describes a failure diagnosis method and a failure diagnosis system that specify a failure spot of a delay failure with a high degree of accuracy. Japanese Patent No. 5381591 describes a delay analysis device, a delay analysis method, and a delay analysis program that can conduct an analysis while deleting a false path that cannot be logically opened, and can obtain an analysis result correlated to reality. Japanese Patent No. 4020731 describes a failure diagnosis method for a semiconductor integrated circuit that can efficiently narrow down a delay failure spot in a short period of time in a delay failure diagnosis for a semiconductor integrated circuit.

### SUMMARY

In the failure diagnosis for a semiconductor integrated circuit as described in Japanese Patent Nos. 5292164, 5381591, and 4020731, a fail log of the delay failure is changed depending on the test conditions. However, the failure spot cannot be sufficiently narrowed down in many cases because the diagnosis is performed on the basis of the fail log obtained under a single condition in an analysis site.

For example, in the case where the number of fails contained in the test result is small, the narrowing accuracy is deteriorated, and many nets are output as failure candidates. If the number of failure candidates is large, the success rate of a physical analysis is reduced, and the cause of the failure cannot be determined.

In particular, an SDL (Soft Defect Localization) analysis is conducted for a delay failure in many cases. The SDL analysis is conducted under conditions at the boundary where the test result shows “pass” or “fail”. Thus, if the fail log is collected in consideration of this, only one to a few fails are obtained, resulting in deterioration in the diagnostic accuracy. Accordingly, it is necessary to obtain the appropriate number of fails by optimizing the test conditions for the delay failure diagnosis.

The other objects and novel features will become apparent from the description of the specification and the accompanying drawings.

(1) A failure diagnosis system in an embodiment includes a control unit, a creation unit, an extraction unit, an analysis unit, a computing unit, and an output unit. The control unit controls a test device to test an integrated circuit a plurality of times while changing the test conditions to collect a fail log. The creation unit creates a test result map on the basis of the fail log collected under the control of the control unit. The extraction unit performs route tracking from a fail flip-flop in the fail log collected under the control of the control unit to obtain a primary failure candidate net. The analysis unit computes by a simulation the delay and timing margin of the fail flip-flop in the fail log collected under the control of the control unit. The computing unit computes a matching degree between the timing margin of the simulation result computed by the analysis unit and the test result map created by the creation unit for each primary failure candidate obtained by the extraction unit. The output unit outputs a candidate having a high matching degree as a failure candidate on the basis of the result computed by the computing unit.

(2) A failure diagnosis method in another embodiment includes a first step, a second step, a third step, a fourth step, a fifth step, and a sixth step as information processing steps by a computer system. In the first step, a test device is controlled to test an integrated circuit a plurality of times while changing the test conditions to collect a fail log. In the second step, a test result map is created on the basis of the fail log collected in the first step. In the third step, route tracking is performed from a fail flip-flop in the fail log collected in the first step to obtain a primary failure candidate net. In the fourth step, the delay and timing margin of the fail flip-flop in the fail log collected in the first step are computed by a simulation. In the fifth step, a matching degree between the timing margin of the simulation result computed in the fourth step and the test result map created in the second step is computed for each primary failure candidate obtained in the third step. In the sixth step, a candidate having a high matching degree is output as a failure candidate on the basis of the result computed in the fifth step.

(3) A failure diagnosis program in still another embodiment includes a first step, a second step, a third step, a fourth step, a fifth step, and a sixth step executed by a computer system. Processes performed in the first to sixth steps correspond to the first to sixth steps in the failure diagnosis method, respectively.

According to an embodiment, the diagnostic accuracy can be improved by obtaining the appropriate number of fails while optimizing test conditions for a delay failure diagnosis.

### BRIEF DESCRIPTION OF THE DRAWINGS

FIG. 1 is a diagram for showing an example of a configuration of a failure diagnosis system according to a first embodiment of the present invention;

FIG. 2 is a diagram for showing an example of a processing procedure of a failure diagnosis method in the failure diagnosis system of FIG. 1;

FIG. 3 is a diagram for showing an example of a flow of data in the processing procedure of the failure diagnosis method of FIG. 2;

FIG. 4 is a diagram for showing an example of a test result map in the processing procedure of the failure diagnosis method of FIG. 2;

FIG. 5 is a diagram for showing an example of a method of obtaining a primary failure candidate net in the processing procedure of the failure diagnosis method of FIG. 2;

FIG. 6 is a diagram for showing an example of a circuit configuration of a sequential circuit in a method of computing a timing margin in the processing procedure of the failure diagnosis method of FIG. 2;

FIG. 7 is a diagram for showing an example of operation waveforms of a clock and each net in FIG. 6;

FIG. 8 is a diagram for showing an example of a simulation result of the timing margin in a method of computing a matching degree in the processing procedure of the failure diagnosis method of FIG. 2;

FIG. 9 is a diagram for showing an example of a procedure when computing the matching degree in the method of computing the matching degree in the processing procedure of the failure diagnosis method of FIG. 2;

FIG. 10 is a diagram for showing an example of a procedure when computing a matching degree in a processing procedure of a failure diagnosis method in a failure diagnosis system according to a third embodiment of the present invention;

FIG. 11 is a diagram for showing an example of a processing procedure of a failure diagnosis method in a failure diagnosis system according to a fourth embodiment of the present invention; and

FIG. 12 is a diagram for showing an example of a processing procedure of a failure diagnosis method in a failure diagnosis system according to a fifth embodiment of the present invention.

### DETAILED DESCRIPTION

The present invention will be described using the following embodiments while being divided into a plurality of sections or embodiments if necessary for convenience sake. However, except for a case especially specified, the sections or embodiments are not irrelevant to each other, and one has a relationship with a part of a modified example or a complete modified example, or a detailed or supplementary explanation of the other.

Further, if the specification refers to the number of elements (including the number of pieces, values, amounts, ranges, and the like) in the following embodiments, the present invention is not limited to the specific number, but may be smaller or larger than the specific number, except for a case especially specified or a case obviously limited to the specific number in principle.

Furthermore, it is obvious that the constitutional elements (including elemental steps and the like) are not necessarily essential in the following embodiments, except for a case especially specified or a case obviously deemed to be essential in principle.

As similar to the above, if the specification refers to the shapes or positional relationships of constitutional elements in the following embodiments, the present invention includes those that are substantially close or similar to the constitutional elements in shapes and the like, except for a case especially specified or a case obviously deemed not to be close or similar in principle. The same applies to the values and ranges.

### Outline of Embodiment

First, an outline of embodiments will be described. As an example, the outline of embodiments will be described while corresponding constitutional elements or signs in the embodiments are given in parentheses.

(1) A failure diagnosis system in an embodiment includes a control unit (test control unit 221), a creation unit (test result map creation unit 222), an extraction unit (primary failure candidate extraction unit 223), an analysis unit (timing analysis unit 224), a computing unit (matching degree computing unit 225), and an output unit (result output unit 226). The control unit controls a test device to test an integrated circuit a plurality of times while changing the test conditions to collect a fail log. The creation unit creates a test result map on the basis of the fail log collected under the control of the control unit. The extraction unit performs route tracking from a fail flip-flop in the fail log collected under the control of the control unit to obtain a primary failure candidate net. The analysis unit computes by a simulation the delay and timing margin of the fail flip-flop in the fail log collected under the control of the control unit. The computing unit computes a matching degree between the timing margin of the simulation result computed by the analysis unit and the test result map created by the creation unit for each primary failure candidate obtained by the extraction unit. The output unit outputs a candidate having a high matching degree as a failure candidate on the basis of the result computed by the computing unit.

(2) A failure diagnosis method in another embodiment includes a first step (S11), a second step (S12), a third step (S13), a fourth step (S14), a fifth step (S15), and a sixth step (S16) as information processing steps by a computer system. In the first step, a test device is controlled to test an integrated circuit a plurality of times while changing the test conditions to collect a fail log. In the second step, a test result map is created on the basis of the fail log collected in the first step. In the third step, route tracking is performed from a fail flip-flop in the fail log collected in the first step to obtain a primary failure candidate net. In the fourth step, the delay and timing margin of the fail flip-flop in the fail log collected in the first step are computed by a simulation. In the fifth step, a matching degree between the timing margin of the simulation result computed in the fourth step and the test result map created in the second step is computed for each primary failure candidate obtained in the third step. In the sixth step, a candidate having a high matching degree is output as a failure candidate on the basis of the result computed in the fifth step.

(3) A failure diagnosis program in still another embodiment includes a first step, a second step, a third step, a fourth step, a fifth step, and a sixth step executed by a computer system. Processes performed in the first to sixth steps correspond to the first to sixth steps in the failure diagnosis method, respectively.

Hereinafter, embodiments on the basis of the above-described outline of embodiments will be described in detail with reference to the drawings. It should be noted that the same or relevant signs are assigned to the same members in principle in the all drawings for explaining the embodiments, and the repetitive explanations will be omitted.

### First Embodiment

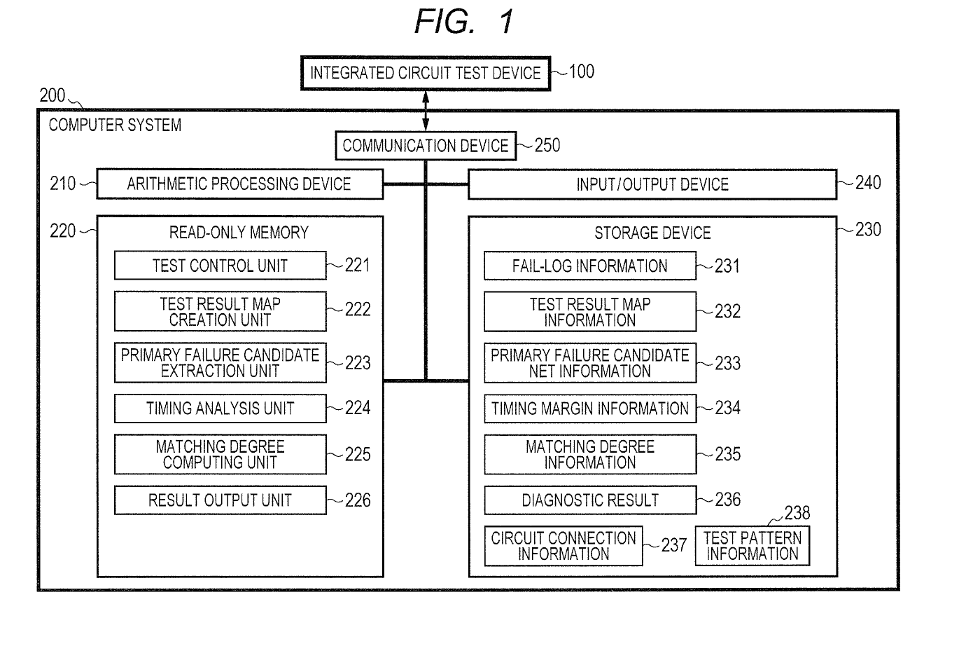

A failure diagnosis system, a failure diagnosis method, and a failure diagnosis program in a first embodiment will be described using FIG. 1 to FIG. 9.

As a technique of improving diagnostic accuracy by optimizing test conditions, tests are conducted a plurality of times while changing the test conditions (timing and the like), and a test result map is created by collecting a fail log to secure the predetermined number of fails in the first embodiment.

### <Failure Diagnosis System>

First, a failure diagnosis system in the first embodiment will be described with reference to FIG. 1. FIG. 1 is a diagram for showing an example of a configuration of the failure diagnosis system in the first embodiment.

The failure diagnosis system in the first embodiment includes an integrated circuit test device 100 and a computer system 200. The computer system 200 includes an arithmetic processing device 210, a read-only memory 220, a storage device 230, and an input/output device 240. The integrated circuit test device 100 and the computer system 200 transmit and receive information to/from each other through a communication device 250.

As an example of the computer system 200, assumed is a computer such as a PC (Personal Computer), a thin client terminal/server, a workstation, a mainframe, or a supercomputer. It should be noted that the computer system 200 of the embodiment is not limited to a terminal or a server, but may be a relay device or a peripheral device. Further, the computer system 200 of the embodiment may be an extension board mounted on a computer or a virtual machine established on a physical machine. However, the present invention is not actually limited to these examples.

The input/output device 240 is used to instruct to start or finish a test or a diagnosis, to read data, or to output a result. As an example of the input device of the input/output device 240, there is a keyboard, a keypad, an I/O board, a keypad on a screen, a touch panel, a tablet, or a reading device to read an IC chip or a storage medium. Further, the input device may be an interface to obtain information from an external input device or storage device. On the other hand, as an example of the output device, there is a display device such as an LCD (Liquid Crystal Display), a PDP (Plasma Display), or an organic EL display, or a printing device such as a printer to print output content on a sheet of paper. Further, the output device may be an interface to output information to an external display device or storage device.

The read-only memory 220 stores therein programs to control the entire operation and to perform a diagnostic process. As the programs, there are a test control unit 221, a test result map creation unit 222, a primary failure candidate extraction unit 223, a timing analysis unit 224, a matching degree computing unit 225, and a result output unit 226. As an example of the read-only memory 220, there is a semiconductor storage device such as a ROM, an EEPROM, or a flash memory.

The arithmetic processing device 210 reads the programs from the read-only memory 220 to run the same, and functions as the test control unit 221, the test result map creation unit 222, the primary failure candidate extraction unit 223, the timing analysis unit 224, the matching degree computing unit 225, and the result output unit 226 to realize a diagnostic process. The programs are failure diagnosis programs. As an example of the arithmetic processing device 210, there is a CPU, a microprocessor, a microcontroller, or a semiconductor integrated circuit having a dedicated function.

The storage device 230 is an area where various pieces of data used for the diagnostic process are temporarily stored. As the data, there are Fail-Log information 231, test result map information 232, primary failure candidate net information 233, timing margin information 234, matching degree information 235, a diagnostic result 236, circuit connection information 237, and test pattern information 238. As an example of the storage device 230, there is an auxiliary storage device such as an HDD (Hard Disk Drive) or an SSD (Solid State Drive), or a semiconductor storage device such as a RAM. Further, the storage device 230 may be a removable disk or a storage medium such as a DVD (Digital Versatile Disk) or an SD memory card (Secure Digital memory card).

The test control unit 221 is a functional unit that controls the integrated circuit test device 100 in such a manner that tests are conducted for a diagnosis target chip a plurality of times while changing the test conditions and the Fail-Log information 231 is generated and output as test results.

The test result map creation unit 222 is a functional unit that inputs the Fail-Log information 231 to create and output a test result map (test result map information 232).

The primary failure candidate extraction unit 223 is a functional unit that inputs the Fail-Log information 231 to obtain and output a primary failure candidate net (primary failure candidate net information 233) on the basis of route tracking of a circuit starting from a fail flip-flop (Fail-FF).

The timing analysis unit 224 is a functional unit that inputs the Fail-Log information 231 to compute the timing margin of the Fail-FF by a simulation (dynamic timing analysis), and generates and outputs the timing margin information 234.

The matching degree computing unit 225 is a functional unit that inputs the primary failure candidate net information 233, the timing margin information 234, and the test result map information 232 to compute a matching degree between the timing margin information 234 and the test result map information 232 for each primary failure candidate net information 233, and generates and outputs the matching degree information 235.

The result output unit 226 is a functional unit that inputs the matching degree information 235 to output a primary failure candidate having a high matching degree as a probable failure candidate (diagnostic result 236).

The Fail-Log information 231 is information generated as a test result obtained by conducting tests for the diagnosis target chip a plurality of times while changing the test conditions. In the test conditions, a case in which the circuit ran as expected is referred to as “pass”, and a case in which the circuit ran not as expected is referred to as “fail”.

The test result map information 232 is information of the test result map created on the basis of the Fail-Log information 231.

The primary failure candidate net information 233 is information of the primary failure candidate net obtained by the route tracking of the circuit starting from the Fail-FF on the basis of the Fail-Log information 231.

The timing margin information 234 is information of the timing margin of the Fail-FF computed by a simulation on the basis of the Fail-Log information 231.

The matching degree information 235 is information generated by computing a matching degree between the timing margin information 234 and the test result map information 232 for each primary failure candidate net information 233 on the basis of the primary failure candidate net information 233, the timing margin information 234, and the test result map information 232.

The diagnostic result 236 is information of a primary failure candidate having a high matching degree output as a probable failure candidate on the basis of the matching degree information 235.

The circuit connection information 237 is information in which connection relations of circuit elements in the integrated circuit of the diagnosis target chip are described, and is also referred to as a net list.

The test pattern information 238 is pattern information of a test signal to confirm that the integrated circuit of the diagnosis target chip normally runs, and represents a signal waveform applied to the integrated circuit in the test. The test pattern information 238 is generated as expected values of a test signal pattern and a signal pattern on the basis of the circuit connection information 237 by, for example, an ATPG (Automatic Test Pattern Generator). The test signal pattern is information to confirm whether or not the circuit normally runs. The expected value of the signal pattern is information output from the circuit that normally runs (is not broken) when the test signal is applied to the circuit.

### <Failure Diagnosis Method>

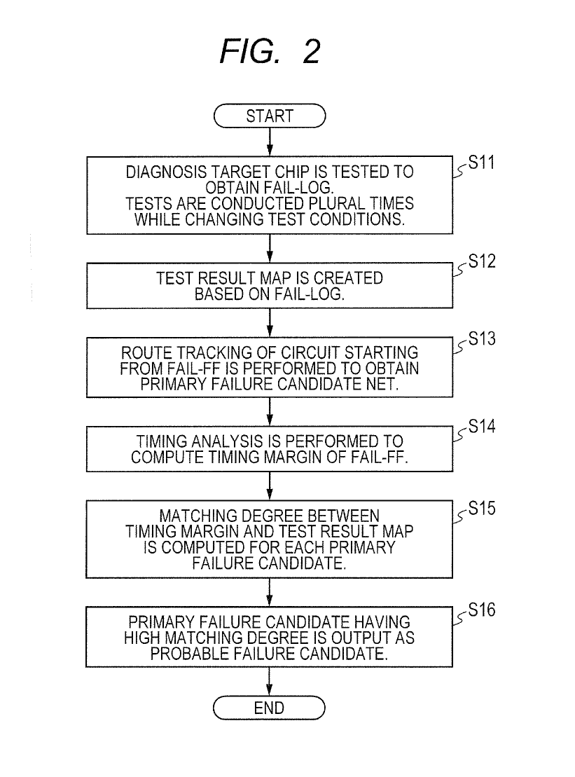

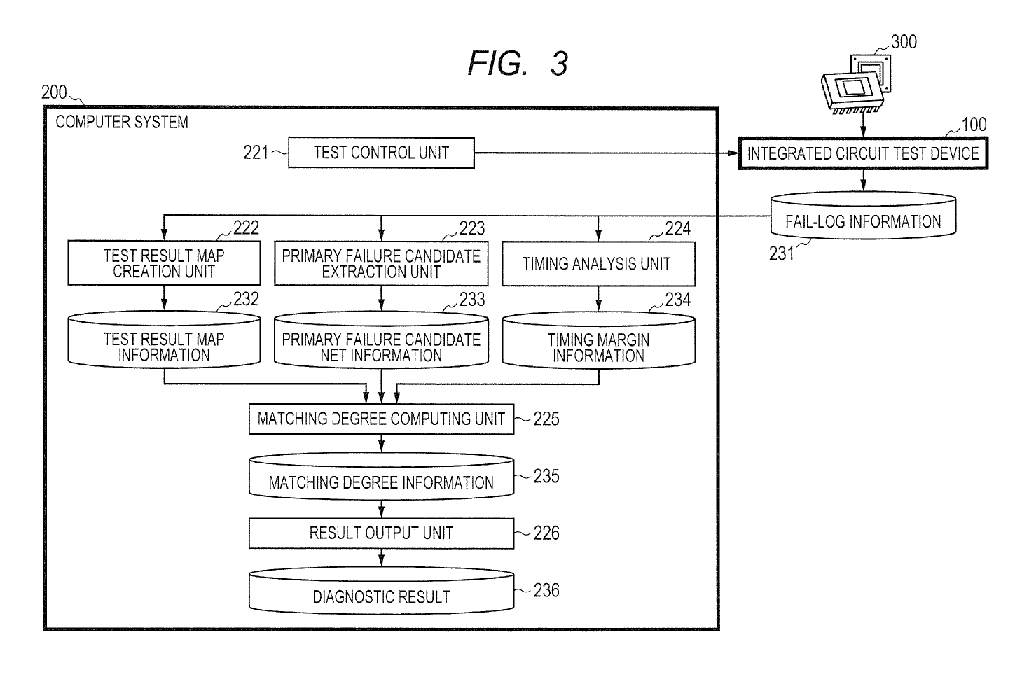

A failure diagnosis method in the above-described failure diagnosis system will be described with reference to FIG. 2 and FIG. 3. FIG. 2 is a diagram for showing an example of a processing procedure of the failure diagnosis method. FIG. 3 is a diagram for showing an example of a flow of data in the processing procedure of the failure diagnosis method.

First, a diagnosis target chip 300 is tested using the integrated circuit test device 100 in Step S11, and the Fail-Log information 231 is generated as a test result. The Fail-Log information 231 is recorded in the storage device 230. In this case, the test control unit 221 controls the integrated circuit test device 100 to conduct the tests for the diagnosis target chip 300 a plurality of times while changing the test conditions.

Next, the test result map creation unit 222 creates the test result map on the basis of the Fail-Log information 231 in Step S12. The test result map corresponds to the test result map information 232.

Next, the primary failure candidate extraction unit 223 obtains the primary failure candidate net by the route tracking of the circuit starting from the Fail-FF on the basis of the Fail-Log information 231 in Step S13. The primary failure candidate net corresponds to the primary failure candidate net information 233. The Fail-FF represents a flip-flop for which one or more test results showed “fail” in the tests. It should be noted that a detailed method of obtaining the primary failure candidate net will be described later.

Next, the timing analysis unit 224 performs a timing analysis on the basis of the Fail-Log information 231 in Step S14, and computes the timing margin of the Fail-FF by a simulation to generate the timing margin information 234.

Then, the matching degree computing unit 225 computes a matching degree between the timing margin information 234 and the test result map information 232 for each primary failure candidate net information 233, and generates the matching degree information 235 in Step S15.

Finally, the result output unit 226 outputs a primary failure candidate having a high matching degree in the matching degree information 235 as a probable failure candidate in Step S16. The primary failure candidate corresponds to the diagnostic result 236.

If the cause of the occurrence of the failure is clarified by the diagnostic result 236 output from the failure diagnosis system, the manufacturing process of the integrated circuit is improved on the basis of the cause, and the probability of the occurrence of the failure is reduced.

Further, in order to recognize the cause of the failure in more detail, a more detailed analysis such as exposure of a failure spot using an FIB (Focused Ion Beam) device and observation of the failure spot using an electron microscope such as an SIM (Scanning Ion Microscope) is performed to improve the manufacturing process in some cases.

### <Test Result Map>

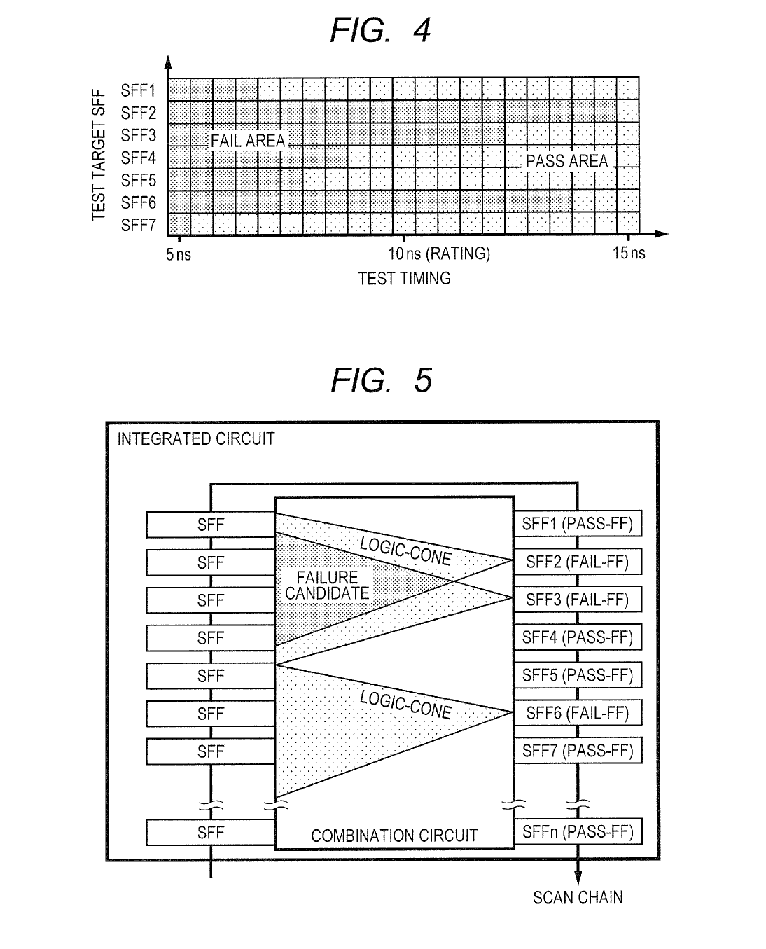

The test result map in Step S12 will be described with reference to FIG. 4. FIG. 4 is a diagram for showing an example of the test result map.

The test result map is a diagram in which fails or passes as the test results for respective scan flip-flops (SFFs) are mapped and the horizontal axis represents the test condition. In FIG. 4, the “test condition” is test timing. The test result map represents a test result of one fail pattern, and the similar test result maps the number of which corresponds to that of fail patterns are created.

The example of FIG. 4 shows a test result in which the test timing as the test condition is changed from 5 ns to 15 ns relative to a rating of 10 ns. In the range from 5 ns to 15 ns, an SFF1 to an SFF7 among n-pieces of scan flip-flops SFF1 to SFFn are determined as “fail”. For example, there is no scan flip-flop determined as “fail” at a test timing of 15 ns. However, the scan flip-flops SFF2, SFF3, and SFF6 are determined as “fail” at a rating of 10 ns, and further the scan flip-flops SFF1 to SFF7 are determined as “fail” at a stricter test timing of 5 ns.

The test timing corresponds to a test rate or the timing of applying the capture clock. Further, the range of the test condition is set on the basis of the experience of an operator who conducts the failure diagnosis, or on the basis of a physical factor such as the capacity of a memory storing the test results.

### <Method of Obtaining Primary Failure Candidate Net>

The method of obtaining the primary failure candidate net in Step S13 will be described with reference to FIG. 5. FIG. 5 is a diagram for showing an example of the method of obtaining the primary failure candidate net.

In the integrated circuit shown in FIG. 5, illustrated is an example in which n-pieces of scan flip-flops (SFFs) are coupled to each of the input and output sides of a combination circuit to configure a scan chain. Among the n-pieces of scan flip-flops on the output side in the example, the SFF2, SFF3, and SFF6 are fail flip-flops (Fail-FFs), and the SFF1, SFF4, SFF5, and SFF7 are pass flip-flops (Pass-FFs). This is associated with the test result at 10 ns (rating) in FIG. 4.

When obtaining the primary failure candidate net, the input side of the circuit is first traced starting from the Fail-FF. The trace is stopped when reaching another SFF. If such a trace is performed, a circuit area in a cone shape having the Fail-FF as an apex is extracted, and is referred to as “Logic-Cone”. Then, the primary failure candidate net is obtained from the net included in the Logic-Cone.

In this case, there are various possible methods such as a method of setting the all nets included in the Logic-Cone as the primary failure candidates and a method of setting only the net where many cones are overlapped as the primary failure candidate. However, any one of the methods may be used in the embodiment.

### <Computing Method of Timing Margin>

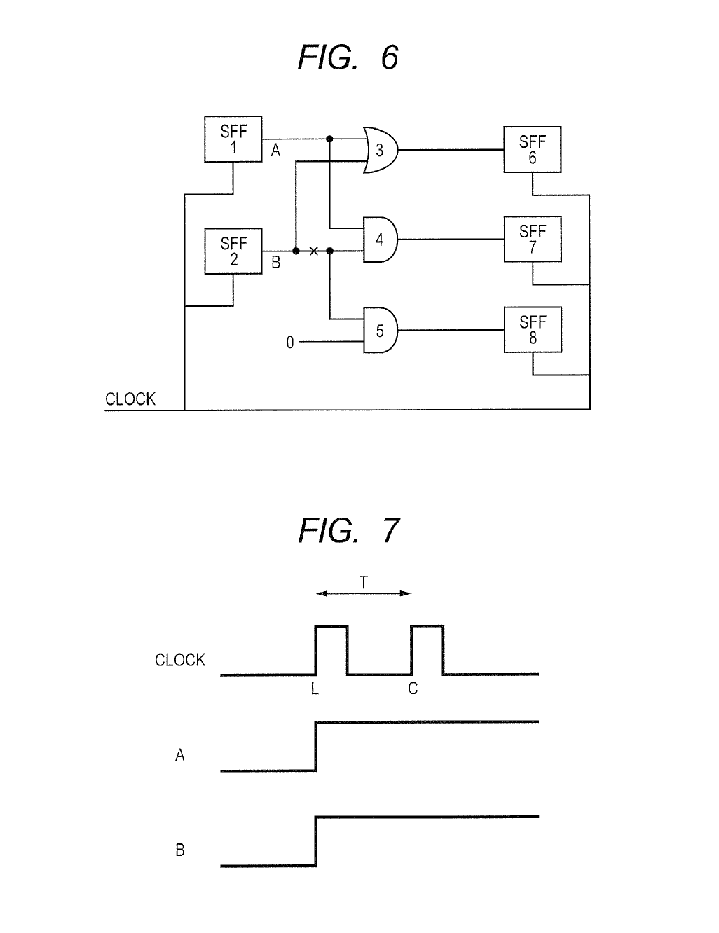

The computing method of the timing margin in Step S14 will be described with reference to FIG. 6 and FIG. 7. FIG. 6 is a diagram for showing an example of a circuit configuration of a sequential circuit. FIG. 7 is a diagram for showing an example of operation waveforms of the clock and each net in FIG. 6.

In the sequential circuit shown in FIG. 6, illustrated is an example configured using the scan flip-flops SFF1, SFF2, SFF6, SFF7, and SFF8, a gate element (OR element) 3, a gate element (AND element) 4, and a gate element (AND element) 5. Delays among the input and output terminals of the SFF1 and SFF2 and the gate elements 3, 4, and 5 are represented by t1 to t5. Further, a delay failure occurs at a position X, and a delay increased amount caused by the failure is represented by td.

FIG. 7 shows operation waveforms of the clock and the nets A and B in FIG. 6. The SFF1 and SFF2 perform a launch operation with a first rising transition (L) of the clock. Accordingly, the rising transition occurs in each of the nets A and B. The SFF6, SFF7, and SFF8 perform a capture operation with a second rising transition (C) of the clock.

A procedure of a timing analysis in the circuit is as follows. First, a time reference (time 0) is set at the first rising transition time (L) of the clock. Thus, the transition time of the net A is t1, and the transition time of the net B is t2. Next, the transition time in the output (input of the SFF6) of the gate element 3 is represented by min (t1, t2)+t3. The “min” represents a function returning the minimum value of arguments. In the gate element 3, simultaneous rising transitions occur at a plurality of input terminals of the OR element. In this case, the transition time of the output is determined on the basis of the transition time of the terminal where the first transition occurred. The function min is used to obtain the first transition time.

On the other hand, the capture operation in the SFF6 is performed at time T in FIG. 7. Accordingly, the timing margin corresponds to a difference between the capture time T and the transition time. Namely, the timing margin in the SFF6 is represented by T−(min (t1, t2)+t3).

As similar to the above, the transition time in the output (input of the SFF7) of the gate element 4 is represented by max (t1, t2+td)+t4. The function max returns the maximum value of arguments. In the gate element 4, simultaneous rising transitions occur at a plurality of input terminals of the AND element. In this case, the transition time of the output is determined on the basis of the transition time of the terminal where the final transition occurred. The function max is used to obtain the final transition time. Further, the failure X exists on the route from the SFF2 to the gate element 4. Accordingly, the delay increased amount td caused by the failure is added when computing the margin. Then, the timing margin in the SFF7 is represented by T−(max (t1, t2+td)+t4).

It should be noted that the propagation of the transition in the SFF8 is blocked by the gate element 5, and thus no fail occurs in the SFF8 in computation. In the case where a fail occurred at the SFF8 in the test result map, the fact is inconsistent with the result of the simulation. Thus, the failure X of FIG. 6 is determined as not a real failure.

It should be noted that as the delay values t1 to t5 of the respective elements, those described in the SDF (Standard Delay Format) file are used. The SDF is information used for timing verification when designing a circuit, and is generated using a parasitic RC extraction tool and a delay computation tool on the basis of the circuit layout.

On the other hand, not only the delay information of elements, but also the delay information of wirings is described in the SDF. In the embodiment, the timing is obtained while disregarding the delays of the wirings to simplify the explanation. Actually, the timing margin should be computed in consideration of the delays of the wirings.

### <Computing Method of Matching Degree>

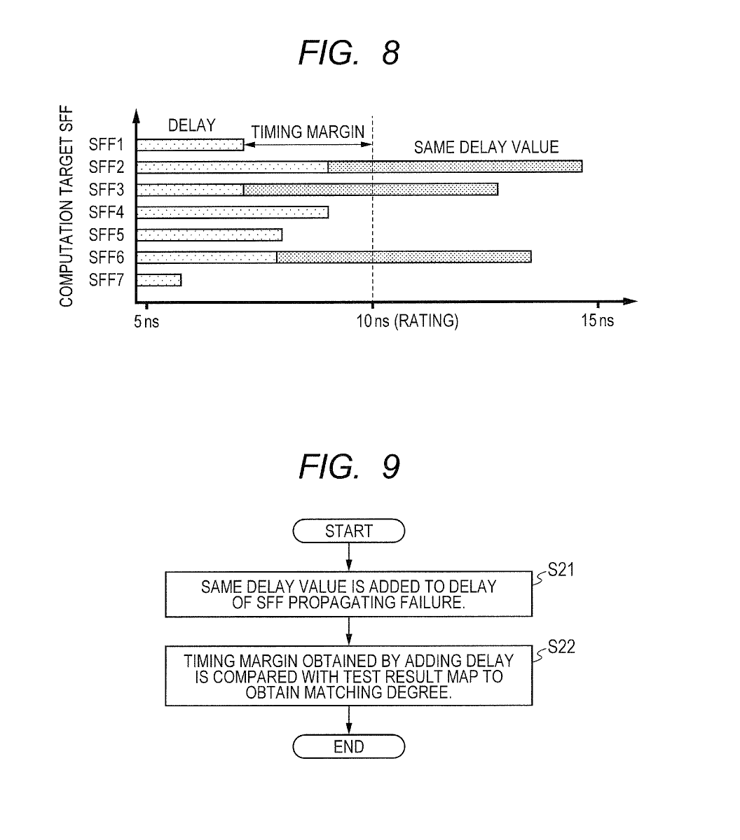

The computing method of the matching degree in Step S15 will be described with reference to FIG. 8 and FIG. 9. FIG. 8 is a diagram for showing an example of a simulation result of the timing margin. FIG. 9 is a diagram for showing an example of a procedure when computing the matching degree.

The simulation result of the timing margin shown in FIG. 8 is a result of obtaining the delay and timing margin of each scan flip-flop (SFF) by a simulation.

In the example of FIG. 8, the delay and timing margin in the simulation result of each scan flip-flop (SFF) are shown while the horizontal axis represents the test condition (test timing), as similar to the test result map shown in FIG. 4.

When computing the matching degree, in the first place, the same delay value as the influence of the failure is added to the delay of each scan flip-flop that propagates the failure from the primary failure candidate net, as shown in FIG. 9 (Step S21). FIG. 8 shows a computing method in the case where the failure is propagated to the SFF2, SFF3, and SFF6. The delay value to be added in this case is determined in such a manner that the delays of the SFF2, SFF3, and SFF6 in FIG. 8 are compared with the test result map of FIG. 4 and the residual is minimized. In the case of the delay failure, the variation of the delay differs depending on the size of the failure, and thus such an operation is performed to express this. Then, the timing margin after adding the delay is compared with the test result map of FIG. 4, and the matching degree in a graph shape is used as the certainty of the failure candidate (Step S22).

### Effect of First Embodiment

According to the above-described embodiment, the test conditions are optimized for the delay failure diagnosis, and the number of fails is set at an appropriate number. Accordingly, the diagnostic accuracy can be improved. Specifically, in the case where the number of fails included in the test result is small, the failure spot cannot be sufficiently narrowed down even by the diagnosis performed by software in some cases. However, the tests are conducted under various conditions in the embodiment, and the diagnosis is performed on the basis of changes in the fail occurrence state due to the test condition. Thus, the problem of deterioration in the diagnostic accuracy as in the case of the small number of fails can be avoided.

Further, the number of fails is increased by simply making the test conditions stricter, so that the diagnostic accuracy can be improved. However, if the test conditions are too strict, a fail possibly occurs at a scan flip-flop that normally runs (is unrelated to a failure). If the diagnosis is performed on the basis of a fail occurring at a normal scan flip-flop, a wrong net is diagnosed as a failure spot. However, according to the method of the embodiment, the diagnosis is performed on the basis of changes in the fail occurrence state due to the test condition, and thus such a wrong diagnosis can be prevented.

### Second Embodiment

A failure diagnosis system, a failure diagnosis method, and a failure diagnosis program in a second embodiment will be described. In the second embodiment, aspects different from those of the first embodiment will be mainly described.

The second embodiment shows a concrete example of the matching degree computing unit 225 in the first embodiment. Specifically, the second embodiment is characterized in that when the matching degree computing unit 225 computes the matching degree between the timing margin information 234 and the test result map information 232 for each primary failure candidate net information 233, an index such as a Pearson's product-moment correlation coefficient is used as an index to represent the matching degree.

The Pearson's product-moment correlation coefficient is a statistical index that represents a correlation (degree of similarity) between two random variables. In principle, there is no unit, and real numbers from −1 to 1 are used. When the number is close to 1, there is a positive correlation between two random variables. When the number is close to −1, there is a negative correlation. When the number is close to 0, the correlation between the original random variables is weak.

### <Pearson's Product-Moment Correlation Coefficient>

The Pearson's product-moment correlation coefficient a can be obtained by the following equation. In this case, xᵢ represents the timing margin of the scan flip-flop SFFi (i=1 to n) obtained from the test result map, yᵢ represents the timing margin of the scan flip-flop SFFi obtained from the simulation, n represents the number of fail flip-flops, and /x and /y represent the arithmetic averages of xᵢ and yᵢ, respectively (“/” represents an upper bar described on the upper side of each of x and y).

$$a = \frac{{\sum }_{i = 1}^{n} ( {x}_{i} - \overline{x} ) \cdot ( {y}_{i} - \overline{y} )}{\sqrt{{\sum }_{i = 1}^{n} {( {x}_{i} - \overline{x} )}^{2}} \cdot \sqrt{{\sum }_{i = 1}^{n} {( {y}_{i} - \overline{y} )}^{2}}} \qquad [ Equation 1 ]$$

The computed result of the Pearson's product-moment correlation coefficient a by the above equation falls within a range from −1 to +1. As the value is larger, the matching degree between xᵢ and yᵢ is high. Accordingly, the Pearson's product-moment correlation coefficient a is used as the matching degree in the first embodiment.

Further, as an index to represent the matching degree, not only the Pearson's product-moment correlation coefficient, but also the cosine similarity can be used.

The cosine similarity is a similarity computing method used when comparing documents with each other in a vector space model. The cosine similarity expresses the similarity of angles formed by vectors. Thus, as the normal cosine of the trigonometric function, when the value is close to 1, the both are similar. When the value is close to 0, the both are not similar.

Even in the above-described embodiment, effects similar to those in the first embodiment can be obtained. In addition, according to the second embodiment, the matching degree between the timing margin computation result and the test result can be evaluated using an objective index. Thus, the objectivity of the diagnostic result can be enhanced. Further, an automatic process by software can be easily performed.

### Third Embodiment

A failure diagnosis system, a failure diagnosis method, and a failure diagnosis program in a third embodiment will be described. In the third embodiment, aspects different from those of the first and second embodiments will be mainly described.

The third embodiment is different from the first embodiment in the computing method of the matching degree by the matching degree computing unit 225. Specifically, the third embodiment is characterized in that the affine transformation is performed for the all delay values before the influence of the failure is added to the delay in the computing method of the matching degree by the matching degree computing unit 225.

The affine transformation is a method of moving and transforming a figure or a shape by combining Euclidean geometric linear transformation (turning, scaling, and shearing) with parallel movement. When the affine transformation is performed for the delay value that is a one-dimensional scalar quantity, the transformation equation is as follows. It should be noted that x and y represent the delay values before and after the transformation, respectively, and a and b represent coefficients.

y=ax+b

### <Computing Method of Matching Degree>

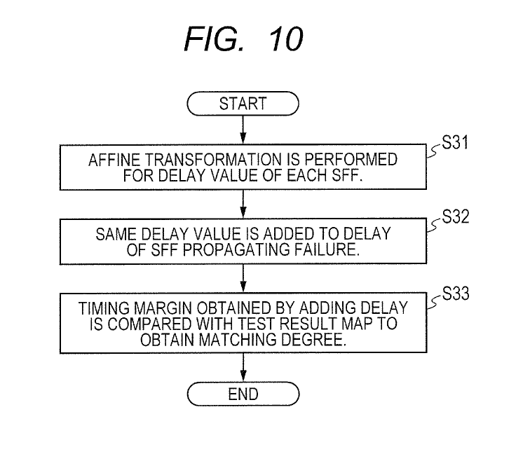

The computing method of the matching degree in the embodiment will be described with reference to FIG. 10. FIG. 10 is a diagram for showing an example of a procedure when computing the matching degree.

When computing the matching degree, the affine transformation is first performed for the delay values of the all scan flip-flops before the influence of the failure is added to the delay of each scan flip-flop propagating the failure (Step S31). The coefficient of the affine transformation is determined in such a manner that the computed values of the timing margins of the scan flip-flops (SFF1, SFF4, SFF5, and SFF7) that do not propagate the failure in the simulation of FIG. 8 are compared with the measurement value of the test in FIG. 4 and the residual is minimized.

After performing the affine transformation, the same delay value as the influence of the failure is added to the delay of each of the scan flip-flops (SFF2, SFF3, and SFF6) propagating the failure, as similar to the first embodiment (Step S32). Then, the timing margin after adding the delay is compared with the test result map of FIG. 4, and the matching degree in a graph shape is used as the certainty of the failure candidate (Step S33).

Even in the above-described embodiment, effects similar to those in the first embodiment can be obtained. In addition, according to the third embodiment, errors of the computed values of the timing margins generated due to variations in manufacturing can be corrected, and the diagnostic accuracy can be improved.

### Fourth Embodiment

A failure diagnosis system, a failure diagnosis method, and a failure diagnosis program in a fourth embodiment will be described. In the fourth embodiment, aspects different from those of the first to third embodiments will be mainly described.

The fourth embodiment is different from the first embodiment in that a non-defective sample and a defective sample are used as the diagnosis target chips 300. Specifically, the fourth embodiment is characterized in that the test result maps are created for both of the non-defective sample and the defective sample, and the test result of the non-defective sample is used in place of the computed result of the timing margin.

### <Failure Diagnosis Method>

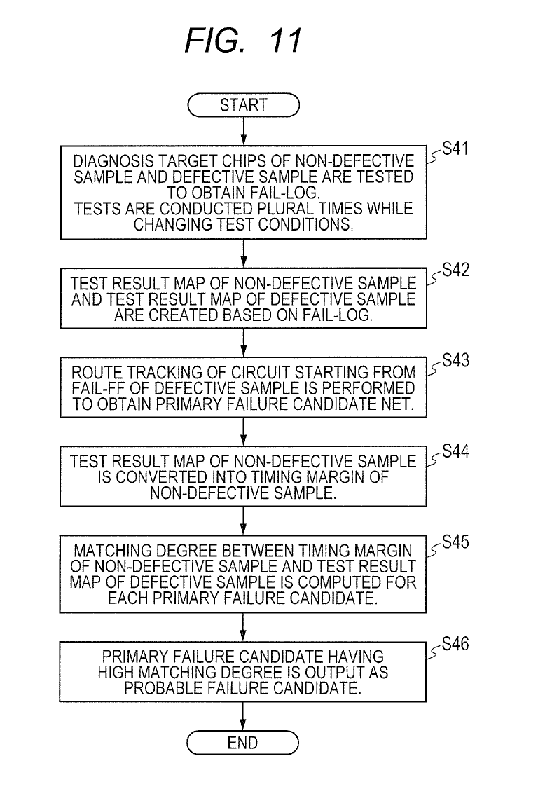

The failure diagnosis method in the embodiment will be described with reference to FIG. 11. FIG. 11 is a diagram for showing an example of a processing procedure of the failure diagnosis method.

First, the diagnosis target chips 300 of the non-defective sample and the defective sample are tested using the integrated circuit test device 100 in Step S41, and the Fail-Log information 231 is generated as the test result. The Fail-Log information 231 is recorded in the storage device 230. In this case, the test control unit 221 controls the integrated circuit test device 100 to test the diagnosis target chips 300 of the non-defective sample and the defective sample a plurality of times while changing the test conditions.

Next, the test result map creation unit 222 creates the test result map of the non-defective sample and the test result map of the defective sample on the basis of the Fail-Log information 231 in Step S42. These maps correspond to the test result map information 232.

Next, the primary failure candidate extraction unit 223 obtains the primary failure candidate net by the route tracking of the circuit starting from the Fail-FF of the defective sample on the basis of the Fail-Log information 231 in Step S43. The primary failure candidate net corresponds to the primary failure candidate net information 233.

Next, the timing analysis unit 224 converts the test result map information 232 of the non-defective sample into the timing margin information 234 of the non-defective sample in Step S44. The test result map information 232 of the non-defective sample shows the timing margin in a state where there is no failure in the sample. Thus, the test result map information 232 can be transformed into the timing margin information 234 as it is.

Then, the matching degree computing unit 225 computes a matching degree between the timing margin information 234 of the non-defective sample and the test result map information 232 of the defective sample for each primary failure candidate net information 233, and generates the matching degree information 235 in Step S45.

Finally, the result output unit 226 outputs a primary failure candidate having a high matching degree in the matching degree information 235 as a probable failure candidate in Step S46. The primary failure candidate corresponds to the diagnostic result 236.

As the non-defective sample and the defective sample in the embodiment, it is conceivable that, for example, if the sample becomes defective only under a high-temperature condition, the test result maps are created under two conditions of low and high temperatures, and the test result of the low temperature is used in place of the computed result of the timing margin. Alternatively, it is conceivable that if the sample becomes defective only under a low power supply voltage condition, the test result maps are created under two conditions of low and high voltages, and the test result of the high voltage is used in place of the computed result of the timing margin.

Even in the above-described embodiment, effects similar to those in the first embodiment can be obtained. In addition, according to the fourth embodiment, the following effects can be obtained. For example, the timing analysis of the integrated circuit contains errors in the computed result in many cases, and the errors possibly deteriorate the diagnostic accuracy. Since the diagnosis is performed using the valuation result of the non-defective sample as the timing margin of the non-defective sample in the embodiment, the influence of the above-described computation errors can be eliminated.

### Fifth Embodiment

A failure diagnosis system, a failure diagnosis method, and a failure diagnosis program in a fifth embodiment will be described. In the fifth embodiment, aspects different from those of the first to fourth embodiments will be mainly described.

The fifth embodiment is different from the first embodiment in that a plurality of samples is used as the diagnosis target chips 300. Specifically, the fifth embodiment is characterized in that a plurality of samples is diagnosed to statistically clarify the main mode of the defect on the basis of the obtained result.

### <Failure Diagnosis Method>

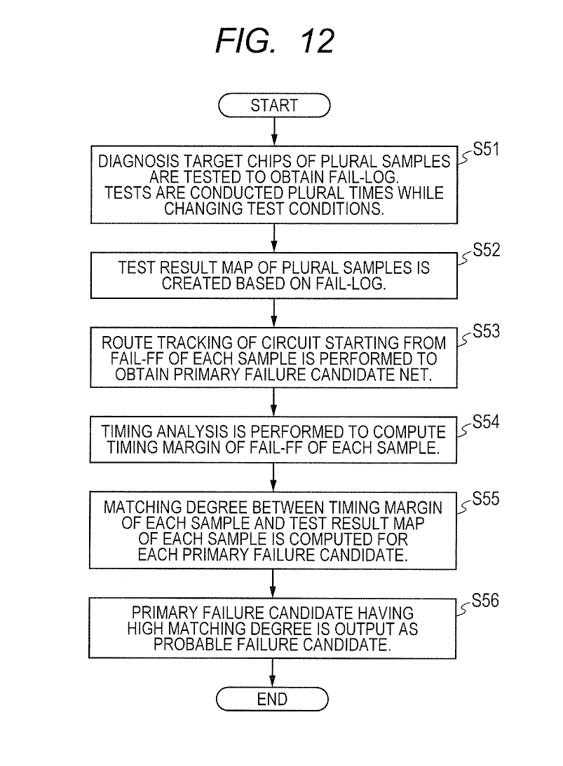

The failure diagnosis method in the embodiment will be described with reference to FIG. 12. FIG. 12 is a diagram for showing an example of a processing procedure of the failure diagnosis method.

First, the diagnosis target chips 300 of the samples are tested using the integrated circuit test device 100 in Step S51, and the Fail-Log information 231 is generated as the test result. The Fail-Log information 231 is recorded in the storage device 230. In this case, the test control unit 221 controls the integrated circuit test device 100 to test the diagnosis target chips 300 of the samples a plurality of times while changing the test conditions.

Next, the test result map creation unit 222 creates the test result map of the samples on the basis of the Fail-Log information 231 in Step S52. The map corresponds to the test result map information 232.

Next, the primary failure candidate extraction unit 223 obtains the primary failure candidate net by the route tracking of the circuit starting from the Fail-FFs of the samples on the basis of the Fail-Log information 231 in Step S53. The primary failure candidate net corresponds to the primary failure candidate net information 233.

Next, the timing analysis unit 224 performs the timing analysis on the basis of the Fail-Log information 231 to compute the timing margins of the Fail-FFs of the samples by a simulation, and generates the timing margin information 234 in Step S54.

Then, the matching degree computing unit 225 computes a matching degree between the timing margin information 234 of the samples and the test result map information 232 of the samples for each primary failure candidate net information 233, and generates the matching degree information 235 in Step S55.

Finally, the result output unit 226 outputs a primary failure candidate having a high matching degree in the matching degree information 235 as a probable failure candidate in Step S56. The primary failure candidate corresponds to the diagnostic result 236.

The failure candidate output from the result output unit 226 is analyzed to clarify the cause of occurrence of the failure. For example, even in the case of a sample passing under the rating condition, the timing margin obtained as a result of measurement in which the test condition is changed to that stricter than the rating significantly differs from the computed value of the timing margin in some cases. In such a case, the diagnosis and analysis are performed on the assumption that some trouble occurs in the sample to clarify the cause.

As a method of determining the main mode of the defect, for example, if the defects occur at the same location in a plurality of samples, this is the main mode. Alternatively, there is a possible method of determining the main mode by a failure layer analysis. The failure layer analysis is a method of clarifying a layer causing the defect on the basis of a result of a statistical analysis for a wiring layer and a via layer contained in the failure candidate net obtained as a diagnostic result.

Even in the above-described embodiment, effects similar to those in the first embodiment can be obtained. In addition, according to the fifth embodiment, the main mode of the defect is clarified, and thus the yield can be improved. Alternatively, the product quality can be improved by taking measures against minute defects that do not appear in a normal test result.

The invention made by the inventors has been described above in detail on the basis of the embodiments. However, it is obvious that the present invention is not limited to the embodiments, but can be variously changed without departing from the scope of the invention.

What is claimed is:

1. A failure diagnosis system comprising:
a control unit that controls a test device to test an integrated circuit a plurality of times while changing the test conditions to collect a fail log;
a creation unit that creates a test result map on the basis of the fail log collected under the control of the control unit;
an extraction unit that performs route tracking from a fail flip-flop in the fail log collected under the control of the control unit to obtain a primary failure candidate net;
an analysis unit that computes by a simulation the delay and timing margin of the fail flip-flop in the fail log collected under the control of the control unit;
a computing unit that computes a matching degree between the timing margin of the simulation result computed by the analysis unit and the test result map created by the creation unit for each primary failure candidate obtained by the extraction unit; and
an output unit that outputs a candidate having a high matching degree as a failure candidate on the basis of the result computed by the computing unit.

2. The failure diagnosis system according to claim 1,
wherein the test result map is a diagram obtained by mapping fails or passes of the test results for respective scan flip-flops on the basis of a change of the test conditions.

3. The failure diagnosis system according to claim 2,
wherein the matching degree is computed in such a manner that the same delay value as the influence of the failure is added to the delay of each scan flip-flop that propagates the failure from the primary failure candidate net,
wherein the delay value is determined in such a manner that the delay of each scan flip-flop that propagates the failure is compared with the test result map, and the residual is minimized, and
wherein the timing margin after adding the delay value is compared with the test result map, and the matching degree in a graph shape is used as the certainty of the failure candidate.

4. The failure diagnosis system according to claim 3,
wherein the test condition is a test rate or test timing including timing of applying a capture clock.

5. The failure diagnosis system according to claim 1,
wherein the computing unit uses either of a product-moment correlation coefficient or cosine similarity as an index representing the matching degree between the timing margin of the simulation result computed by the analysis unit and the test result map created by the creation unit.

6. The failure diagnosis system according to claim 1,
wherein before the same delay value as the influence of the failure is added to the delay of each scan flip-flop that propagates the failure from the primary failure candidate net, the computing unit performs affine transformation for each delay value, and
wherein the coefficient of the affine transformation is determined in such a manner that the timing margin of each scan flip-flop that propagates no failure from the primary failure candidate net is compared with the test result map, and the residual is minimized.

7. The failure diagnosis system according to claim 1,
wherein the integrated circuits are integrated circuits of a non-defective sample and a defective sample,
wherein the control unit controls the test device to test the integrated circuits of the non-defective sample and the defective sample a plurality of times while changing the test conditions to collect the fail log,
wherein the creation unit creates test result maps of the non-defective sample and the defective sample on the basis of the fail log collected under the control of the control unit,
wherein the extraction unit performs route tracking from a fail flip-flop of the defective sample in the fail log collected under the control of the control unit to obtain a primary failure candidate of a primary failure candidate net,
wherein the analysis unit obtains the timing margin of the non-defective sample by transforming from the test result map of the non-defective sample created by the creation unit,
wherein the computing unit computes a matching degree between the timing margin of the non-defective sample obtained by the analysis unit and the test result map of the defective sample created by the creation unit for each primary failure candidate obtained by the extraction unit, and
wherein the output unit outputs a candidate having a high matching degree as a failure candidate on the basis of the result computed by the computing unit.

8. The failure diagnosis system according to claim 7,
wherein the non-defective sample and the defective sample become those due to temperature conditions.

9. The failure diagnosis system according to claim 1,
wherein the integrated circuits are integrated circuits of a plurality of samples,
wherein the control unit controls the test device to test the integrated circuits of the samples a plurality of times while changing the test conditions to collect the fail log,
wherein the creation unit creates a test result map of the samples on the basis of the fail log collected under the control of the control unit,
wherein the extraction unit performs route tracking from a fail flip-flop of each sample in the fail log collected under the control of the control unit to obtain a primary failure candidate of a primary failure candidate net,
wherein the analysis unit computes by a simulation the delay and timing margin of the fail flip-flop of each sample in the fail log collected under the control of the control unit,
wherein the computing unit computes a matching degree between the timing margin of the simulation result in each sample computed by the analysis unit and the test result map of the samples created by the creation unit for each primary failure candidate obtained by the extraction unit,
wherein the output unit outputs a candidate having a high matching degree as a failure candidate on the basis of the result computed by the computing unit, and
wherein the failure candidate output from the output unit is analyzed to clarify the cause of occurrence of the failure.

10. A failure diagnosis method, comprising, as information processing steps by a computer system:
a first step of controlling a test device to test an integrated circuit a plurality of times while changing the test conditions to collect a fail log;
a second step of creating a test result map on the basis of the fail log collected in the first step;
a third step of performing route tracking from a fail flip-flop in the fail log collected in the first step to obtain a primary failure candidate net;
a fourth step of computing by a simulation the delay and timing margin of the fail flip-flop in the fail log collected in the first step;
a fifth step of computing a matching degree between the timing margin of the simulation result computed in the fourth step and the test result map created in the second step for each primary failure candidate obtained in the third step; and
a sixth step of outputting a candidate having a high matching degree as a failure candidate on the basis of the result computed in the fifth step.

11. The failure diagnosis method according to claim 10,
wherein the test result map is a diagram obtained by mapping fails or passes of the test results for respective scan flip-flops on the basis of a change of the test conditions.

12. The failure diagnosis method according to claim 11,
wherein the matching degree is computed in such a manner that the same delay value as the influence of the failure is added to the delay of each scan flip-flop that propagates the failure from the primary failure candidate net,
wherein the delay value is determined in such a manner that the delay of each scan flip-flop that propagates the failure is compared with the test result map, and the residual is minimized, and
wherein the timing margin after adding the delay value is compared with the test result map, and the matching degree in a graph shape is used as the certainty of the failure candidate.

13. A failure diagnosis program allowing a computer system to execute:
a first step of controlling a test device to test an integrated circuit a plurality of times while changing the test conditions to collect a fail log;
a second step of creating a test result map on the basis of the fail log collected in the first step;
a third step of performing route tracking from a fail flip-flop in the fail log collected in the first step to obtain a primary failure candidate net;
a fourth step of computing by a simulation the delay and timing margin of the fail flip-flop in the fail log collected in the first step;
a fifth step of computing a matching degree between the timing margin of the simulation result computed in the fourth step and the test result map created in the second step for each primary failure candidate obtained in the third step; and
a sixth step of outputting a candidate having a high matching degree as a failure candidate on the basis of the result computed in the fifth step.

14. The failure diagnosis program according to claim 13,
wherein the test result map is a diagram obtained by mapping fails or passes of the test results for respective scan flip-flops on the basis of a change of the test conditions.

15. The failure diagnosis program according to claim 14,
wherein the matching degree is computed in such a manner that the same delay value as the influence of the failure is added to the delay of each scan flip-flop that propagates the failure from the primary failure candidate net,
wherein the delay value is determined in such a manner that the delay of each scan flip-flop that propagates the failure is compared with the test result map, and the residual is minimized, and
wherein the timing margin after adding the delay value is compared with the test result map, and the matching degree in a graph shape is used as the certainty of the failure candidate.
